(19) United States
(12) Patent Application Publication
(10) Pub. No.: US 2024/0074239 A1
(43) Pub. Date: Feb. 29, 2024

(54) DISPLAY DEVICE

(71) Applicant: Samsung Display Co., LTD., Yongin-si (KR)

(72) Inventor: XINXING LI, Yongin-si (KR)

(21) Appl. No.: 18/131,533

(22) Filed: Apr. 6, 2023

(30) Foreign Application Priority Data
Aug. 23, 2022 (KR) 10-2022-0105786

(51) Int. Cl. H10K 59/122; G09G 3/3233; H10K 59/12

(52) U.S. Cl. CPC H10K 59/122; G09G 3/3233; H10K 59/1201; G09G 2300/0819; G09G 2300/0842

(57) ABSTRACT

A display device includes a substrate including a pixel area and a non-pixel area adjacent to the pixel area, a planarization layer disposed on the substrate and including a plurality of protrusions each having a planar shape surrounding a center of the pixel area, a pixel electrode disposed on the planarization layer and overlapping the pixel area, a pixel defining layer disposed on the planarization layer, overlapping the non-pixel area, and exposing a portion of the pixel electrode, a lower light emitting layer disposed on the pixel electrode, a charge generation layer disposed on the lower light emitting layer, and an upper light emitting layer disposed on the charge generation layer.

This application claims priority to Korean Patent Application No. 10-2022-0105786, filed on Aug. 23, 2022, and all the benefits accruing therefrom under 35 U.S.C. § 119, the content of which in its entirety is herein incorporated by reference.

### BACKGROUND

### 1. Field

Embodiments relate to a display device. More particularly, embodiments relate to a display device for providing visual information.

### 2. Description of the Related Art

As information technology develops, the importance of display devices, which are communication media between users and information, is being highlighted. Accordingly, display devices such as liquid crystal display devices, organic light emitting display devices, plasma display devices, and the like are widely used in various fields.

A display device may include light emitting diodes, and the light emitting diode includes a pixel electrode, a common electrode, and a light emitting layer disposed between the pixel electrode and the common electrode. In such a display device, functional layers (e.g., a hole transport layer, an electron transport layer, an auxiliary layer, etc.) may be further disposed above and below the light emitting layer to improve the light emitting efficiency of the light emitting diode.

### SUMMARY

Embodiments provide a display device with improved display quality.

A display device according to an embodiment includes a substrate including a pixel area and a non-pixel area adjacent to the pixel area, a planarization layer disposed on the substrate and including a plurality of protrusions each having a planar shape surrounding a center of the pixel area, a pixel electrode disposed on the planarization layer and overlapping the pixel area, a pixel defining layer disposed on the planarization layer, overlapping the non-pixel area, and exposing a portion of the pixel electrode, a lower light emitting layer disposed on the pixel electrode, a charge generation layer disposed on the lower light emitting layer, and an upper light emitting layer disposed on the charge generation layer.

In an embodiment, the charge generation layer may be continuously disposed over the pixel area and the non-pixel area.

In an embodiment, the pixel electrode may be disposed along a profile of the planarization layer.

In an embodiment, the pixel defining layer may include a first pixel defining layer contacting a portion of the pixel electrode and a second pixel defining layer surrounding the first pixel defining layer on a plane, and the first pixel defining layer and the second pixel defining layer may be spaced apart from each other.

In an embodiment, the first pixel defining layer may contact one side surface of a protrusion among the protrusions, and the second pixel defining layer may overlap another protrusion among the protrusions.

In an embodiment, the lower light emitting layer and the upper light emitting layer may overlap the pixel area.

In an embodiment, the lower light emitting layer may be disposed along a profile of the pixel electrode.

In an embodiment, the upper light emitting layer may be disposed along a profile of the charge generation layer.

In an embodiment, the display device may further include a common electrode disposed on the upper light emitting layer.

In an embodiment, the common electrode may be continuously disposed over the pixel area and the non-pixel area.

In an embodiment, the protrusions may include a first protrusion overlapping a center of the pixel area, at least one second protrusion surrounding the first protrusion, and a third protrusion surrounding the second protrusion.

In an embodiment, each of the protrusions may have a polygonal cross-sectional shape.

In an embodiment, each of the protrusions may have a semicircular or semielliptical cross-sectional shape.

In an embodiment, the charge generation layer may include a first charge generation layer disposed on the lower light emitting layer and a second charge generation layer disposed on the first charge generation layer.

In an embodiment, the display device may further include an electron transport layer respectively disposed on the lower light emitting layer and on the upper light emitting layer.

In an embodiment, the display device may further include a hole transport layer respectively disposed under the lower light emitting layer and under the upper light emitting layer.

A display device according to an embodiment includes a substrate including a first pixel area which emits a first light, a second pixel area which emits a second light different from the first light, and a non-pixel area adjacent to the first pixel area and the second pixel area, a planarization layer disposed on the substrate and including a plurality of protrusions each having a planar shape surrounding a center of the first pixel area and a center of the second pixel area, a first pixel electrode disposed on the planarization layer and overlapping the first pixel area, a second pixel electrode disposed on the planarization layer and overlapping the second pixel area, a pixel defining layer disposed on the planarization layer, overlapping the non-pixel area, and exposing a portion of each of the first pixel electrode and the second pixel electrode, a first lower light emitting layer disposed on the first pixel electrode, a second lower light emitting layer disposed on the second pixel electrode, a charge generation layer disposed on the first lower light emitting layer and the second lower light emitting layer, a first upper light emitting layer disposed on the charge generation layer and overlapping the first lower light emitting layer, and a second upper light emitting layer disposed on the charge generation layer and overlapping the second lower light emitting layer.

In an embodiment, the charge generation layer may be continuously disposed over the first and second pixel areas and the non-pixel area.

In an embodiment, the first and second pixel electrodes may be disposed along a profile of the planarization layer.

In an embodiment, the pixel defining layer may include a first pixel defining layer contacting portions of the first and second pixel electrodes and a second pixel defining layer surrounding the first pixel defining layer on a plane, and the first pixel defining layer and the second pixel defining layer may be spaced apart from each other.

In a display device according to embodiments of the disclosure, the display device may include a planarization layer, a pixel defining layer, a lower light emitting layer, a charge generation layer and an upper light emitting layer sequentially disposed on a substrate, and the planarization layer may include a plurality of protrusions. In such embodiments, since the area of the charge generation layer disposed on the planarization layer increases and the resistance of the charge generation layer between the lower light emitting layer and the upper light emitting layer decreases, light emitting efficiency of the lower light emitting layer and the upper light emitting layer may be improved.

In such embodiments, as the planarization layer includes the plurality of protrusions and a first pixel defining layer and a second pixel defining layer are spaced apart from each other, the length of the charge generation layer may increase. Accordingly, the resistance of the charge generation layer between adjacent sub-pixels increases and leakage current flowing between adjacent sub-pixels is blocked, thereby effectively preventing color mixing defects between adjacent sub-pixels.

### BRIEF DESCRIPTION OF THE DRAWINGS

FIG. 1 is a plan view illustrating a display device according to an embodiment.

FIG. 2 is a circuit diagram illustrating an embodiment of a first sub-pixel of the display device of FIG. 1.

FIG. 3 is a cross-sectional view taken along line I-I′ of FIG. 1.

FIG. 4 is an enlarged cross-sectional view of an embodiment of a first light emitting element of FIG. 3.

FIG. 5 is an enlarged cross-sectional view of an embodiment of a second light emitting element of FIG. 3.

FIGS. 6 to 16 are views for illustrating an embodiment of a method of manufacturing the display device of FIG. 3.

FIG. 17 is a cross-sectional view corresponding to FIG. 3, illustrating an alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the invention will be described in detail with reference to the accompanying drawings. The same reference numerals are used for the same components in the drawings, and any repetitive detailed descriptions of the same components will be omitted or simplified.

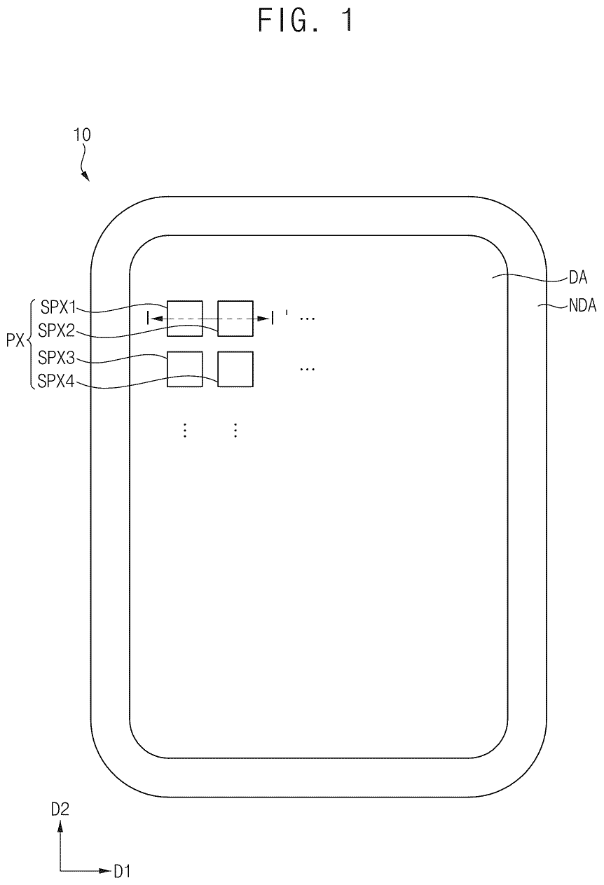

FIG. 1 is a plan view illustrating a display device according to an embodiment.

Referring to FIG. 1, a display device 10 according to an embodiment of the disclosure may include a display area DA and a non-display area NDA. The display area DA may be an area on which an image is displayed by generating light or adjusting transmittance of light provided from an external light source. The non-display area NDA may be an area on which no image is displayed. The non-display area NDA may be located around the display area DA. In an embodiment, for example, the non-display area NDA may entirely surround the display area DA.

On a plane or when viewed in a plan view, the display device 10 may have a rectangular shape with rounded corners. However, the configuration of the disclosure is not limited thereto. In an embodiment, for example, on a plane, the display device 10 may have various shapes (e.g., a rectangular shape with vertical corners).

A plurality of pixels PX may be disposed in the display area DA. In such an embodiment, the display area DA may display an image by emitting light from the plurality of pixels PX.

Each of the plurality of pixels PX may include a first sub-pixel SPX1, a second sub-pixel SPX2, a third sub-pixel SPX3 and a fourth sub-pixel SPX4. The first, second, third and fourth sub-pixels SPX1, SPX2, SPX3 and SPX4 may emit light of different colors from each other or substantially the same color as each other.

In an embodiment, the first sub-pixel SPX1 may be a red sub-pixel that emits red light, the second and third sub-pixels SPX2 and SPX3 may be green sub-pixels that emits green light, and the fourth sub-pixel SPX4 may be a blue sub-pixel that emits blue light. However, the color of light emitted from each of the first, second, third and fourth sub-pixels SPX1, SPX2, SPX3 and SPX4 is not limited thereto. In addition, although FIG. 1 shows an embodiment where each of the plurality of pixels PX includes four sub-pixels SPX1, SPX2, SPX3 and SPX4, the disclosure is not limited thereto.

The first, second, third and fourth sub-pixels SPX1, SPX2, SPX3 and SPX4 may be arranged in various shapes on a plane. In an embodiment, for example, as shown in FIG. 1, the first, second, third and fourth sub-pixels SPX1, SPX2, SPX3 and SPX4 may be arranged to overlap four vertexes of a virtual quadrangle (not shown). However, the disclosure is not limited thereto, and arrangements of the first, second, third and fourth sub-pixels SPX1, SPX2, SPX3 and SPX4 may be variously changed.

The plurality of pixels PX may be repeatedly arranged along a first direction D1 and a second direction D2 crossing the first direction D1. Accordingly, each of the first, second, third and fourth sub-pixels SPX1, SPX2, SPX3 and SPX4 may be repeatedly arranged along the first direction D1 and the second direction D2.

The display device 10 may include driving units disposed in the non-display area NDA. In an embodiment, for example, the driving units may include a gate driving unit, a data driving unit, or the like. The driving units may be electrically connected to the plurality of pixels PX. The driving units may provide signals and voltages for emitting light to the plurality of pixels PX.

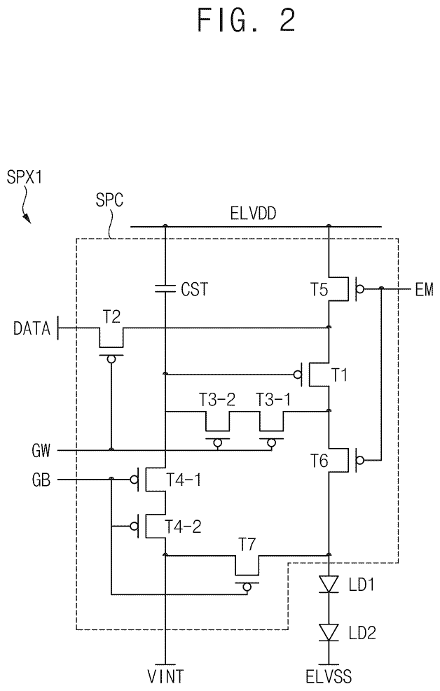

FIG. 2 is a circuit diagram illustrating an embodiment of a first sub-pixel of the display device of FIG. 1.

Referring to FIGS. 1 and 2, an embodiment of the first sub-pixel SPX1 may include first and second light emitting diodes LD1 and LD2 and a sub-pixel circuit SPC for driving the first and second light emitting diodes LD1 and LD2.

Although not shown in FIG. 2, the second, third and fourth sub-pixels SPX2, SPX3 and SPX4 may have the same circuit structure as the first sub-pixel SPX1. That is, the first, second, third and fourth sub-pixels SPX1, SPX2, SPX3 and SPX4 may have the same circuit structure as each other.

The sub-pixel circuit SPC may include first, second, third, fourth, fifth, sixth and seventh transistors T1, T2, T3-1, T3-2, T4-1, T4-2, T5, T6 and T7, a storage capacitor CST, a driving voltage ELVDD line, a common voltage ELVSS line, an initialization voltage VINT line, a data signal DATA line, a scan signal GW line, a data initialization signal GB line, and an light emitting control signal EM line.

The first and second light emitting diodes LD1 and LD2 may form or collectively define one (or a single) light emitting diode. Therefore, hereinafter, the first and second light emitting diodes LD1 and LD2 will be considered as one configuration.

The first and second light emitting diodes LD1 and LD2 may output light based on a driving current. The first and second light emitting diodes LD1 and LD2 may include a first terminal and a second terminal. The first terminal of the first and second light emitting diodes LD1 and LD2 may be connected to a second terminal of the seventh transistor T7. The second terminal of the first and second light emitting diodes LD1 and LD2 may receive the common voltage ELVSS.

The first transistor T1 may include a gate terminal, a first terminal and a second terminal. In an embodiment, for example, the first terminal of the first transistor T1 may be a source terminal, and the second terminal of the first transistor T1 may be a drain terminal. Alternatively, the first terminal of the first transistor T1 may be a drain terminal, and the second terminal of the first transistor T1 may be a source terminal.

The first transistor T1 may generate the driving current. In an embodiment, for example, the first transistor T1 may operate in a saturation area. In this case, the first transistor T1 may generate the driving current based on a voltage difference between the gate terminal and the source terminal. In addition, a grayscale may be expressed based on the magnitude of the driving current supplied to the first and second light emitting diodes LD1 and LD2. In this case, the grayscale may be expressed based on the sum of the times during which the driving current is supplied to the first and second light emitting diodes LD1 and LD2 within one frame.

The second transistor T2 may include a gate terminal, a first terminal and a second terminal. The gate terminal of the second transistor T2 may receive the scan signal GW. The first terminal of the second transistor T2 may receive the data signal DATA. The second terminal of the second transistor T2 may be connected to the first terminal of the first transistor T1. In an embodiment, for example, the first terminal of the second transistor T2 may be a source terminal, and the second terminal of the second transistor T2 may be a drain terminal. Alternatively, the first terminal of the second transistor T2 may be a drain terminal, and the second terminal of the second transistor T2 may be a source terminal.

The second transistor T2 may supply the data signal DATA to the first terminal of the first transistor T1 during an activation period of the scan signal GW. In such an embodiment, the second transistor T2 may operate in a linear area.

The third transistor T3-1 and T3-2 may include a first third transistor T3-1 (hereinafter, will be referred to as “(3-1)th transistor”) and a second third transistor T3-2 (hereinafter, will be referred to as “(3-2)th transistor”). In an embodiment, for example the (3-1)th transistor T3-1 and the (3-2)th transistor T3-2 may be connected to each other in series and may operate as a dual transistor. In an embodiment, for example, when the dual transistor is turned off, leakage current may be reduced.

Each of the (3-1)th transistor T3-1 and the (3-2)th transistor T3-2 may include a gate terminal, a first terminal and a second terminal. The gate terminal of each of the (3-1)th transistor T3-1 and the (3-2)th transistor T3-2 may receive the scan signal GW. The first terminal the (3-1)th transistor T3-1 may be connected to the second terminal of the first transistor T1. The second terminal of the (3-1)th transistor T3-1 may be connected to the first terminal of the (3-2)th transistor T3-2. The second terminal of (3-2)th transistor T3-2 may be connected to the gate terminal of the first transistor T1. In an embodiment, for example, the first terminal of each of the (3-1)th transistor T3-1 and the (3-2)th transistor T3-2 may be a source terminal, and the second terminal of each of the (3-1)th transistor T3-1 and the (3-2)th transistor T3-2 may be a drain terminal. Alternatively, the first terminal of each of the (3-1)th transistor T3-1 and the (3-2)th transistor T3-2 may be a drain terminal, and the second terminal of each of the (3-1)th transistor T3-1 and the (3-2)th transistor T3-2 may be a source terminal.

The third transistor T3-1 and T3-2 may connect the gate terminal of the first transistor T1 and the first terminal of the first transistor T1 to each other during the activation period of the scan signal GW. In this case, the third transistor T3-1 and T3-2 may diode-connect the first transistor T1 during the activation period of the scan signal GW. Since the first transistor T1 is diode-connected, a voltage difference equal to the threshold voltage of the first transistor T1 may occur between the first terminal of the first transistor T1 and the gate terminal of the first transistor T1. As a result, a voltage obtained by adding the voltage difference (i.e., the threshold voltage) to the voltage of the data signal DATA supplied to the first terminal of the first transistor T1 during the activation period of the scan signal GW may be supplied to the gate terminal of the transistor T1. Accordingly, the data signal DATA may be compensated by the threshold voltage of the first transistor T1, and the compensated data signal DATA may be supplied to the gate terminal of the first transistor T1.

The fourth transistor T4-1 and T4-2 may include a (first fourth transistor T4-1 (hereinafter, will be referred to as “(4-1)th transistor”) and a second fourth transistor T4-2 (hereinafter, will be referred to as “(4-2)th transistor”). In an embodiment, for example, the (4-1)th transistor T4-1 and the (4-2)th transistor T4-2 may be connected to each other in series and may operate as a dual transistor. In an embodiment, for example, when the dual transistor is turned off, the leakage current may be reduced.

Each of the (4-1)th transistor T4-1 and the (4-2)th transistor T4-2 may include a gate terminal, a first terminal and a second terminal. The gate terminal of each of the (4-1)th transistor T4-1 and the (4-2)th transistor T4-2 may receive the data initialization signal GB. The first terminal of each of the (4-1)th transistor T4-1 and the (4-2)th transistor T4-2 may receive the initialization voltage VINT. The second terminal of each of the (4-1)th transistor T4-1 and the (4-2)th transistor T4-2 may be connected to the gate terminal of the first transistor T1. In an embodiment, for example, the first terminal of each of the (4-1)th transistor T4-1 and the (4-2)th transistor T4-2 may be a source terminal, and the second terminal of each of the (4-1)th transistor T4-1 and the (4-2)th transistor T4-2 may be a drain terminal. Alternatively, the first terminal of each of the (4-1)th transistor T4-1 and the (4-2)th transistor T4-2 may be a drain terminal, and the second terminal of each of the (4-1)th transistor T4-1 and the (4-2)th transistor T4-2 may be a source terminal.

The fourth transistor T4-1 and T4-2 may supply the initialization voltage VINT to the gate terminal of the first transistor T1 during an activation period of the data initialization signal GB. In this case, the fourth transistor T4-1 and T4-2 may operate in a linear area. That is, the fourth transistor T4-1 and T4-2 may initialize the gate terminal of the first transistor T1 to the initialization voltage VINT during the activation period of the data initialization signal GB.

The fifth transistor T5 may include a gate terminal, a first terminal and a second terminal. The gate terminal of the fifth transistor T5 may receive the light emitting control signal EM. The first terminal of the fifth transistor T5 may receive the driving voltage ELVDD. The second terminal of the fifth transistor T5 may be connected to the first terminal of the first transistor T1. In an embodiment, for example, the first terminal of the fifth transistor T5 may be a source terminal, and the second terminal of the fifth transistor T5 may be a drain terminal. Alternatively, the first terminal of the fifth transistor T5 may be a drain terminal, and the second terminal of the fifth transistor T5 may be a source terminal.

The fifth transistor T5 may supply the driving voltage ELVDD to the first terminal of the first transistor T1 during an activation period of the light emitting control signal EM. In such an embodiment, the fifth transistor T5 may cut off the supply of the driving voltage ELVDD during an inactivation period of the light emitting control signal EM. In this case, the fifth transistor T5 may operate in a linear area. Since the fifth transistor T5 supplies the driving voltage ELVDD to the first terminal of the first transistor T1 during the activation period of the light emitting control signal EM, the first transistor T1 may generate the driving current.

In such an embodiment, since the fifth transistor T5 cuts off the supply of the driving voltage ELVDD during the inactivation period of the light emitting control signal EM, the data signal DATA supplied to the first terminal of the first transistor T1 may be supplied to the gate terminal of the first transistor T1.

The sixth transistor T6 may include a gate terminal, a first terminal and a second terminal. The gate terminal of the sixth transistor T6 may receive the light emitting control signal EM. The first terminal of the sixth transistor T6 may be connected to the second terminal of the first transistor T1. The second terminal of the sixth transistor T6 may be connected to the first terminal of the first and second light emitting diodes LD1 and LD2. In an embodiment, for example, the first terminal of the sixth transistor T6 may be a source terminal, and the second terminal of the sixth transistor T6 may be a drain terminal. Alternatively, the first terminal of the sixth transistor T6 may be a drain terminal, and the second terminal of the sixth transistor T6 may be a source terminal.

The sixth transistor T6 may supply the driving current generated by the first transistor T1 to the first and second light emitting diodes LD1 and LD2 during the activation period of the light emitting control signal EM. In this case, the sixth transistor T6 may operate in a linear area. That is, since the sixth transistor T6 supplies the driving current generated by the first transistor T1 to the first and second light emitting diodes LD1 and LD2 during the activation period of the light emitting control signal EM, the first and second light emitting diodes LD1 and LD2 may emit light. In addition, since the sixth transistor T6 electrically separates the first transistor T1 and the first and second light emitting diodes LD1 and LD2 from each other during the inactivation period of the light emitting control signal EM, the data signal DATA supplied to the second terminal of the first transistor T1 may be supplied to the gate terminal of the first transistor T1.

The seventh transistor T7 may include a gate terminal, a first terminal and the second terminal. The gate terminal of the seventh transistor T7 may receive the data initialization signal GB. The first terminal of the seventh transistor T7 may receive the initialization voltage VINT. The second terminal of the seventh transistor T7 may be connected to the first terminal of the first and second light emitting diodes LD1 and LD2. In an embodiment, for example, the first terminal of the seventh transistor T7 may be a source terminal, and the second terminal of the seventh transistor T7 may be a drain terminal. Alternatively, the first terminal of the seventh transistor T7 may be a drain terminal, and the second terminal of the seventh transistor T7 may be a source terminal.

The seventh transistor T7 may supply the initialization voltage VINT to the first terminal of the first and second light emitting diodes LD1 and LD2 during the activation period of the data initialization signal GB. In this case, the seventh transistor T7 may operate in a linear area. That is, the seventh transistor T7 may initialize the first terminal of the first and second light emitting diodes LD1 and LD2 to the initialization voltage VINT during the activation period of the data initialization signal GB.

The storage capacitor CST may include a first terminal and a second terminal. The storage capacitor CST may be connected between the driving voltage ELVDD line and the gate terminal of the first transistor T1. In an embodiment, for example, the first terminal of the storage capacitor CST may be connected to the gate terminal of the first transistor T1, and the second terminal of the storage capacitor CST may be connected to the driving voltage ELVDD line.

The storage capacitor CST may maintain the voltage level of the gate terminal of the first transistor T1 during an inactivation period of the scan signal GW. The inactivation period of the scan signal GW may include the activation period of the light emitting control signal EM, and the driving current generated by the first transistor T1 during the activation period of the light emitting control signal EM may be supplied to the first and second light emitting diodes LD1 and LD2. Accordingly, the driving current generated by the first transistor T1 based on the voltage level maintained by the storage capacitor CST may be supplied to the first and second light emitting diodes LD1 and LD2.

Although an embodiment of the first sub-pixel SPX1 including seven transistors and one storage capacitor is described above, the configuration of the disclosure is not limited thereto. In an embodiment, for example, the first sub-pixel SPX1 may include at least one transistor and at least one storage capacitor.

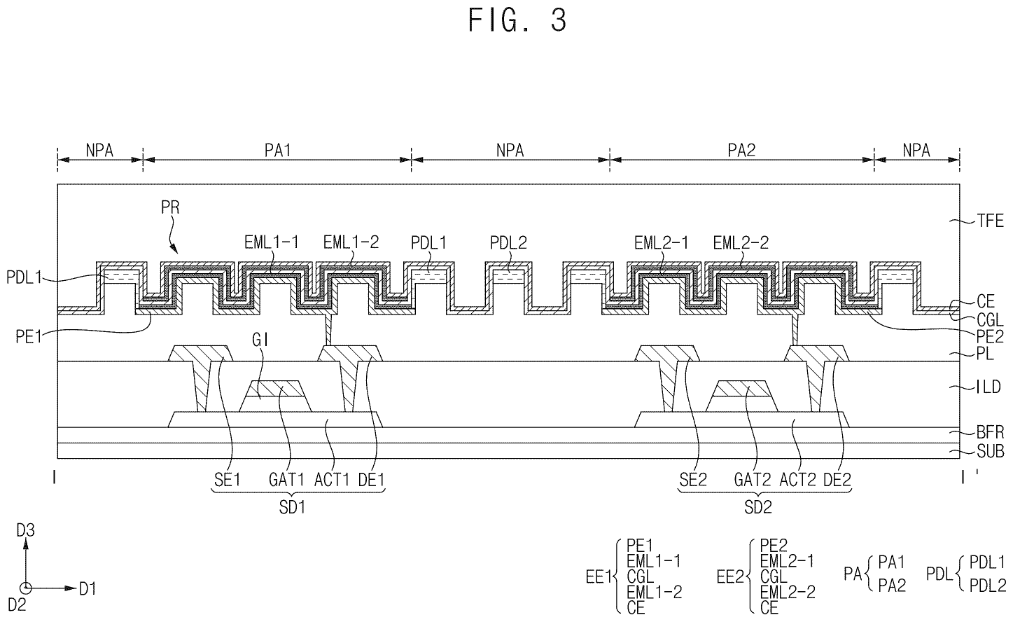

FIG. 3 is a cross-sectional view taken along line I-I′ of FIG. 1. Particularly, FIG. 3 may be a cross-sectional view illustrating an embodiment of the display area DA of the display device 10 of FIG. 1.

Referring to FIG. 3, an embodiment of the display device 10 may include a substrate SUB, a buffer layer BFR, a first semiconductor element SD1, a second semiconductor element SD2, a gate insulating layer GI, an interlayer insulating layer ILD, a planarization layer PL, first and second pixel electrodes PE1 and PE2, a pixel defining layer PDL, first and second lower light emitting layers EML1-1 and EML2-1, a charge generation layer CGL, first and second upper light emitting layers EML1-2 and EML2-2, a common electrode CE, and an encapsulation layer TFE.

The substrate SUB may include a transparent material or an opaque material. In an embodiment, for example, the substrate SUB may include glass, quartz, plastic, or the like. These may be used alone or in combination with each other.

In an embodiment, a pixel area PA and a non-pixel area NPA adjacent to the pixel area PA may be defined on the substrate SUB. In an embodiment, for example, the pixel area PA may be an area that emits light, and the non-pixel area NPA may be an area that does not emit light. The pixel area PA may include a first pixel area PA1 that emits a first light and a second pixel area PA2 that emits a second light different from the first light.

The buffer layer BFR may be disposed on the substrate SUB. The buffer layer BFR may prevent diffusion of metal atoms or impurities from the substrate SUB to the first and second semiconductor elements SD1 and SD2. In addition, the buffer layer BFR may improve flatness of the surface of the substrate SUB when the surface of the substrate SUB is not uniform. The buffer layer BFR may include an inorganic insulating material. In an embodiment, for example, inorganic insulating materials that may be used for the buffer layer BFR may include silicon oxide (SiOₓ), silicon nitride (SiNₓ), silicon oxynitride (SiOₓN_{y}), or the like. These may be used alone or in combination with each other.

The first semiconductor element SD1 may include a first active pattern ACT1, a first gate electrode GAT1, a first source electrode SE1 and a first drain electrode DE1. The second semiconductor element SD2 may include a second active pattern ACT2, a second gate electrode GAT2, a second source electrode SE2 and a second drain electrode DE2.

Each of the first and second active patterns ACT1 and ACT2 may be disposed on the buffer layer BFR. Each of the first and second active patterns ACT1 and ACT2 may include a silicon semiconductor material or an oxide semiconductor material. In an embodiment, for example, silicon semiconductor materials that may be used for each of the first and second active patterns ACT1 and ACT2 may include amorphous silicon, polycrystalline silicon, and the like. In an embodiment, for example, oxide semiconductor materials that may be used for each of the first and second active patterns ACT1 and ACT2 may include indium gallium zinc oxide (IGZO), indium tin zinc oxide (ITZO), or the like. These may be used alone or in combination with each other. Each of the first and second active patterns ACT1 and ACT2 may include a source area, a drain area and a channel area positioned between the source area and the drain area.

The gate insulating layer GI may be disposed on the first and second active patterns ACT1 and ACT2. The gate insulating layer GI may overlap the channel area of each of the first and second active patterns ACT1 and ACT2. The gate insulating layer GI may not overlap the source area and the drain area of each of the first and second active patterns ACT1 and ACT2. The gate insulating layer GI may include an inorganic insulating material. In an embodiment, for example, inorganic insulating materials that may be used for the gate insulating layer GI may include silicon oxide, silicon nitride, silicon oxynitride, or the like. These may be used alone or in combination with each other.

Each of the first and second gate electrodes GAT1 and GAT2 may be disposed on the gate insulating layer GI. Each of the first and second gate electrodes GAT1 and GAT2 may overlap the gate insulating layer GI. Each of the first and second gate electrodes GAT1 and GAT2 may include a conductive material. In an embodiment, for example, conductive materials that may be used for each of the first and second gate electrodes GAT1 and GAT2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), or the like. These may be used alone or in combination with each other.

The interlayer insulating layer ILD may be disposed on the buffer layer BFR. The interlayer insulating layer ILD may cover the first and second active patterns ACT1 and ACT2, the gate insulating layer GI, and the first and second gate electrodes GAT1 and GAT2. In an embodiment, for example, the interlayer insulating layer ILD may sufficiently cover the first and second gate electrodes GAT1 and GAT2, and may have a substantially flat upper surface without creating a step structure around the first and second gate electrodes GAT1 and GAT2. Alternatively, the interlayer insulating layer ILD may cover the first and second gate electrodes GAT1 and GAT2, and may be disposed along a profile of each of the first and second gate electrodes GAT1 and GAT2 with a uniform thickness. The interlayer insulating layer ILD may include an inorganic insulating material. In an embodiment, for example, inorganic insulating materials that may be used for the interlayer insulating layer ILD may include silicon oxide, silicon nitride, silicon oxynitride, or the like. These may be used alone or in combination with each other.

Each of the first and second source electrodes SE1 and SE2 may be disposed on the interlayer insulating layer ILD. The first source electrode SE1 may be connected to the source area of the first active pattern ACT1 through a contact hole defined through the interlayer insulating layer ILD. The second source electrode SE2 may be connected to the source area of the second active pattern ACT2 through a contact hole defined through the interlayer insulating layer ILD.

Each of the first and second drain electrodes DE1 and DE2 may be disposed on the interlayer insulating layer ILD. The first drain electrode DE1 may be connected to the drain area of the first active pattern ACT1 through a contact hole defined through the interlayer insulating layer ILD. The second drain electrode DE2 may be connected to the drain area of the second active pattern ACT2 through a contact hole defined through the interlayer insulating layer ILD.

Each of the first and second source electrodes SE1 and SE2 may include a conductive material. In an embodiment, for example, conductive materials that may be used for each of the first and second source electrodes SE1 and SE2 may include aluminum, platinum, palladium, silver, magnesium, gold, nickel, neodymium, iridium, chromium, lithium, calcium, molybdenum, titanium, tungsten, copper, or the like. These may be used alone or in combination with each other. Each of the first and second drain electrodes DE1 and DE2 may include a same material as the first and second source electrodes SE1 and SE2.

Accordingly, the first semiconductor element SD1 including the first active pattern ACT1, the first gate electrode GAT1, the first source electrode SE1 and the first drain electrode DE1 may be disposed in the first pixel area PA1 on the substrate SUB, and the second semiconductor element SD2 including the second active pattern ACT2, the second gate electrode GAT2, the second source electrode SE2 and the second drain electrode DE2 may be disposed in the second pixel area PA2 on the substrate SUB.

The planarization layer PL may be disposed on the interlayer insulating layer ILD. The planarization layer PL may sufficiently cover the first and second source electrodes SE1 and SE2 and the first and second drain electrodes DE1 and DE2. The planarization layer PL may include an organic insulating material. In an embodiment, for example, organic insulating materials that may be used for the planarization layer PL may include photoresist, polyacrylic resin, polyimide resin, acrylic resin, or the like. These may be used alone or in combination with each other.

In an embodiment, the planarization layer PL may include a plurality of protrusions PR. In an embodiment, for example, the planarization layer PL may overlap the pixel area PA and the non-pixel area NPA, and may include the plurality of protrusions PR protruding from an upper surface of the planarization layer PL in a thickness direction (e.g., a third direction D3). Here, the third direction D3 may be perpendicular to each of the first and second directions D1 and D2.

Each of the protrusions PR may have a polygonal cross-sectional shape. In an embodiment, for example, each of the protrusions PR may have a rectangular cross-sectional shape. However, the cross-sectional shape of each of the protrusions PR is not limited thereto, and each of the protrusions PR may have various cross-sectional shapes.

Each of the first and second pixel electrodes PE1 and PE2 may be disposed on the planarization layer PL. The first pixel electrode PE1 may overlap the first pixel area PA1, and the second pixel electrode PE2 may overlap the second pixel area PA2. In an embodiment, each of the first and second pixel electrodes PE1 and PE2 may be disposed along a profile of the planarization layer PL. In such an embodiment, each of the first and second pixel electrodes PE1 and PE2 may be disposed along a profile of the protrusions PR of the planarization layer PL.

The first pixel electrode PE1 may be connected to the first drain electrode DE1 through a contact hole defined through the planarization layer PL, and the second pixel electrode PE2 may be connected to the second drain electrode DE2 through a contact hole defined through the planarization layer PL. Each of the first and second pixel electrodes PE1 and PE2 may include a conductive material. In an embodiment, for example, conductive materials that may be used for each of the first and second pixel electrodes PE1 and PE2 may include aluminum, platinum, palladium, silver, magnesium, gold, nickel, neodymium, iridium, chromium, lithium, calcium, molybdenum, titanium, tungsten, copper, or the like. These may be used alone or in combination with each other.

The pixel defining layer PDL may be disposed on the planarization layer PL. The pixel defining layer PDL may overlap the non-pixel area NPA, and may expose a portion of each of the first and second pixel electrodes PE1 and PE2.

In an embodiment, the pixel defining layer PDL may include a first pixel defining layer PDL1 and a second pixel defining layer PDL2. In an embodiment, for example, the first pixel defining layer PDL1 and the second pixel defining layer PDL2 may be spaced apart from each other.

In an embodiment, the first pixel defining layer PDL1 may contact portions of each of the first and second pixel electrodes PE1 and PE2. That is, the first pixel defining layer PDL1 may contact ends of each of the first and second pixel electrodes PE1 and PE2. In addition, the first pixel defining layer PDL1 may contact one side surface of a protrusion among the protrusions PR.

In an embodiment, the second pixel defining layer PDL2 may overlap another protrusion among the protrusions PR. In such an embodiment, the second pixel defining layer PDL2 may contact an upper surface of the another protrusion. In such an embodiment, the second pixel defining layer PDL2 may not contact a side surface of the another protrusion.

The pixel defining layer PDL may include an organic insulating material. In an embodiment, for example, organic insulating materials that may be used for the pixel definition layer PDL may include photoresist, polyacrylic resin, polyimide resin, acrylic resin, or the like. These may be used alone or in combination with each other.

The first lower light emitting layer EML1-1 may be disposed on the first pixel electrode PE1, and the second lower light emitting layer EML2-1 may be disposed on the second pixel electrode PE2. That is, the first lower light emitting layer EML1-1 may overlap the first pixel area PA1, and the second lower light emitting layer EML2-1 may overlap the second pixel area PA2. Each of the first and second lower light emitting layers EML1-1 and EML2-1 may be disposed along respective profiles of the first and second pixel electrodes PE1 and PE2.

The first lower light emitting layer EML1-1 may emit first light. In an embodiment, for example, the first light may be red light, and the first lower light emitting layer EML1-1 may include an organic material that emits red light. The second lower light emitting layer EML2-1 may emit a second light different from the first light. In an embodiment, for example, the second light may be green light, and the second lower light emitting layer EML2-1 may include an organic material that emits green light. However, the disclosure is not limited thereto.

The charge generation layer CGL may be disposed on the first and second lower light emitting layers EML1-1 and EML2-1. The charge generation layer CGL may be disposed in the pixel area PA, and may continuously extend from the pixel area PA to the non-pixel area NPA or over the pixel area PA and the non-pixel area NPA. The charge generation layer CGL may be disposed along a profile of the first and second lower light emitting layers EML1-1 and EML2-1, the pixel defining layer PDL and the planarization layer PL.

Each of the first and second upper light emitting layers EML1-2 and EML2-2 may be disposed on the charge generation layer CGL. The first upper light emitting layer EML1-2 may overlap the first pixel area PA1, and the second upper light emitting layer EML2-2 may overlap the second pixel area PA2. That is, the first upper light emitting layer EML1-2 may overlap the first lower light emitting layer EML1-1, and the second upper light emitting layer EML2-2 may overlap the second lower light emitting layer EML2-1. Each of the first and second upper light emitting layers EML1-2 and EML2-2 may be disposed along a profile of the charge generation layer CGL.

The first upper light emitting layer EML1-2 may emit the first light. In an embodiment, for example, the first light may be red light, and the first upper light emitting layer EML1-2 may include an organic material that emits red light. The second upper light emitting layer EML2-2 may emit the second light. In an embodiment, for example, the second light may be green light, and the second upper light emitting layer EML2-2 may include an organic material that emits green light. However, the disclosure is not limited thereto.

The common electrode CE may be disposed on the first and second upper light emitting layers EML1-2 and EML2-2. The common electrode CE may be disposed in the pixel area PA, and may continuously extend from the pixel area PA to the non-pixel area NPA or over the pixel area PA and the non-pixel area NPA. The common electrode CE may be disposed along a profile of the first and second upper light emitting layers EML1-2 and

EML2-2 and the charge generation layer CGL. The common electrode CE may include a conductive material. In an embodiment, for example, the conductive material that may be used for the common electrode CE may include lithium, calcium, aluminum, silver, magnesium, or the like. These may be used alone or in combination with each other.

The first pixel electrode PE1, the first lower light emitting layer EML1-1, the charge generation layer CGL, the first upper light emitting layer EML1-2, and the common electrode CE may form (or collectively define) a first light emitting element EEL The first light emitting element EE1 may overlap the first pixel area PA1.

The second pixel electrode PE2, the second lower light emitting layer EML2-1, the charge generation layer CGL, the second upper light emitting layer EML2-2, and the common electrode CE may form (or collectively define) a second light emitting element EE2. The second light emitting element EE2 may overlap the second pixel area PA2.

The encapsulation layer TFE may be disposed on the common electrode CE. The encapsulation layer may overlap the pixel area PA and the non-pixel area NPA. The encapsulation layer TFE may prevent impurities, moisture, outside air, or the like from permeating the first and second light emitting elements EE1 and EE2 from outside. The encapsulation layer TFE may include at least one inorganic encapsulation layer and at least one organic encapsulation layer.

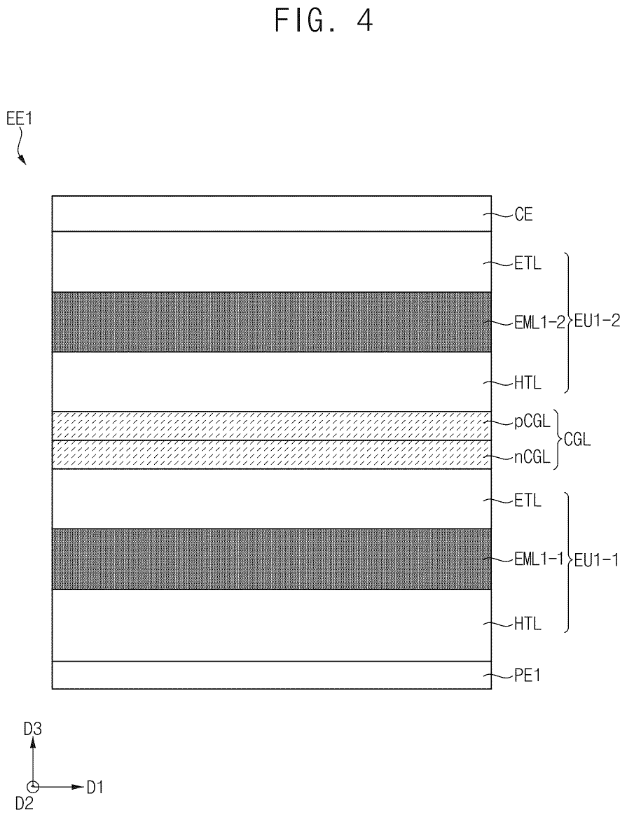

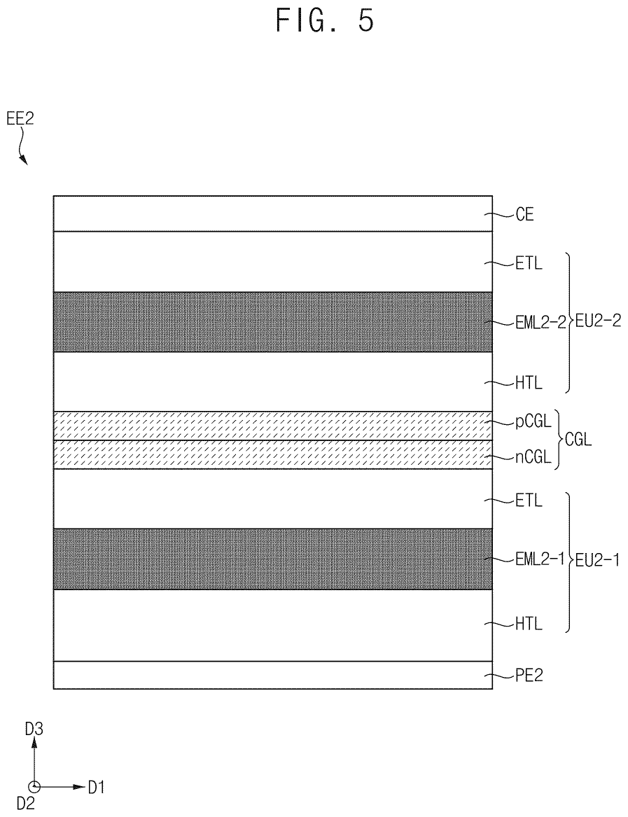

FIG. 4 is an enlarged cross-sectional view of an embodiment of a first light emitting element of FIG. 3. FIG. 5 is an enlarged cross-sectional view of an embodiment of a second light emitting element of FIG. 3.

Referring to FIGS. 3, 4, and 5, the first light emitting element EE1 may include the first pixel electrode PE1, a first first light emitting structure unit EU1-1 (hereinafter, will be referred to as “(1-1)th light emitting structure unit”), the charge generation layer CGL, a second first light emitting structure unit EU1-2 (hereinafter, will be referred to as “(1-2)th light emitting structure unit”), and a common electrode CE. The second light emitting element EE2 may include the second pixel electrode PE2, a first second light emitting structure unit EU2-1 (hereinafter, will be referred to as “(2-1)th light emitting structure unit”), the charge generation layer CGL, a second second light emitting structure unit EU2-2 (hereinafter, will be referred to as “(2-2)th light emitting structure unit”), and the common electrode CE.

Each of the light emitting structure units may include a light emitting layer that generates light according to an applied current. In an embodiment, for example, the (1-1)th light emitting structure unit EU1-1 may include a hole transport layer HTL, the first lower light emitting layer EML1-1 and an electron transport layer ETL, and the (1-2)th light emitting structure unit EU1-2 may include the hole transport layer HTL, the first upper light emitting layer EML1-2 and the electron transport layer ETL. In addition, the (2-1)th light emitting structure unit EU2-1 may include the hole transport layer HTL, the second lower light emitting layer EML2-1 and the electron transport layer ETL, and the (2-2)th light emitting structure unit EU2-2 may include the hole transport layer HTL, the second upper light emitting layer EML2-2 and the electron transport layer ETL.

Each of the hole transport layers HTL of the (1-1)th light emitting structure unit EU1-1 and the (2-1)th light emitting structure unit EU2-1 may be disposed on the first and second pixel electrodes PE1 and PE2. The hole transport layer HTL may overlap the pixel area PA and the non-pixel area NPA. In an embodiment, for example, the hole transport layer HTL may include at least one selected from a hole injection layer and a hole transport layer. Alternatively, the hole transport layer HTL may further include a hole buffer layer, an electron blocking layer, and the like.

The first lower light emitting layer EML1-1 may be disposed on the hole transport layer HTL of the (1-1)th light emitting structure unit EU1-1, and may overlap the first pixel area PA1. When electrons and holes are injected into the first lower light emitting layer EML1-1, the first lower light emitting layer EML1-1 may emit the first light. The second lower light emitting layer EML2-1 may be disposed on the hole transport layer HTL of the (2-1)th light emitting structure unit EU2-1, and may overlap the second pixel area PA2. When electrons and holes are injected into the second lower light emitting layer EML2-1, the second lower light emitting layer EML2-1 may emit the second light.

Each of the electron transport layers ETL of the (1-1)th light emitting structure unit EU1-1 and the (2-1)th light emitting structure unit EU2-1 may be disposed on the first and second lower light emitting layers EML1-1 and EML2-1. The electron transport layer ETL may overlap the pixel area PA and the non-pixel area NPA. In an embodiment, for example, the electron transport layer ETL may include at least one of an electron injection layer and an electron transport layer. Alternatively, the electron transport layer ETL may further include an electron buffer layer, a hole blocking layer, or the like.

The charge generation layer CGL may be disposed on the electron transport layer ETL of each of the (1-1)th light emitting structure unit EU1-1 and the (2-1)th light emitting structure unit EU2-1. The charge generation layer CGL may overlap the pixel area PA and the non-pixel area NPA. The charge generation layer CGL may increase the mobility of electrons toward the first and second lower light emitting layers EML1-1 and EML2-1, and may increase the mobility of holes toward the first and second lower light emitting layers EML1-1 and EML2-1. In an embodiment, the charge generation layer CGL may include a first charge generation layer nCGL and a second charge generation layer pCGL disposed on the first charge generation layer nCGL, and may have a NP junction structure.

Each of the hole transport layers HTL of the (1-2)th light emitting structure unit EU1-2 and the (2-2)th light emitting structure unit EU2-2 may be disposed on the charge generation layer CGL.

The first upper light emitting layer EML1-2 may be disposed on the hole transport layer HTL of the (1-2)th light emitting structure unit EU1-2, and may overlap the first pixel area PA1. When electrons and holes are injected into the first upper light emitting layer EML1-2, the first upper light emitting layer EML1-2 may emit the first light. The second upper light emitting layer EML2-2 may be disposed on the hole transport layer HTL of the (2-2)th light emitting structure unit EU2-2, and may overlap the second pixel area PA2. When electrons and holes are injected into the second upper light emitting layer EML2-2, the second upper light emitting layer EML2-2 may emit the second light.

Each of the electron transport layers ETL of the (1-2)th light emitting structure unit EU1-2 and the (2-2)th light emitting structure unit EU2-2 may be disposed on the first and second upper light emitting layers EML1-2 and EML2-2.

Although embodiments where each of the first light emitting element EE1 and the second light emitting element EE2 includes two light emitting layers are shown in FIGS. 3, 4 and 5, the disclosure is not limited thereto. In an alternative embodiment, for example, each of the first light emitting element EE1 and the second light emitting element EE2 may include three or more light emitting layers.

In an embodiment, two or more light emitting layers may be stacked one on another in each of the first light emitting element EE1 and the second light emitting element EE2, and a charge generation layer may be disposed between the light emitting layers to improve light emitting efficiency and diode lifetime. In such an embodiment, due to the high conductivity of the charge generation layer, leakage current may be generated between adjacent sub-pixels, and color mixing defects between the adjacent sub-pixels may occur.

The display device 10 according to an embodiment of the disclosure may include the planarization layer PL, the pixel defining layer PDL, the lower light emitting layers EML1-1 and EML2-1, the charge generation layer CGL, the upper light emitting layers EML1-2 and EML2-2 sequentially disposed on the substrate SUB, and the planarization layer PL may include the plurality of protrusions PR. In such an embodiment, since the area of the charge generation layer CGL disposed on the planarization layer PL increases and the resistance of the charge generation layer CGL between the lower light emitting layers EML1-1 and EML2-1 and the upper light emitting layers EML1-2 and EML2-2 decreases, such that light emitting efficiency of the lower light emitting layers EML1-1 and EML2-1 and the upper light emitting layers EML1-2 and EML2-2 may be improved.

In such an embodiment, as the planarization layer PL includes the plurality of protrusions PR and the first pixel defining layer PDL1 and the second pixel defining layer PDL2 are spaced apart from each other, the length of the charge generation layer CGL may increase and the resistance of the charge generation layer CGL between adjacent sub-pixels (e.g., the first sub-pixel SPX1 and the second sub-pixel SPX2 of FIG. 1) may increase. Accordingly, leakage current flowing between the adjacent sub-pixels may be blocked, thereby effectively preventing color mixing defects between the adjacent sub-pixels.

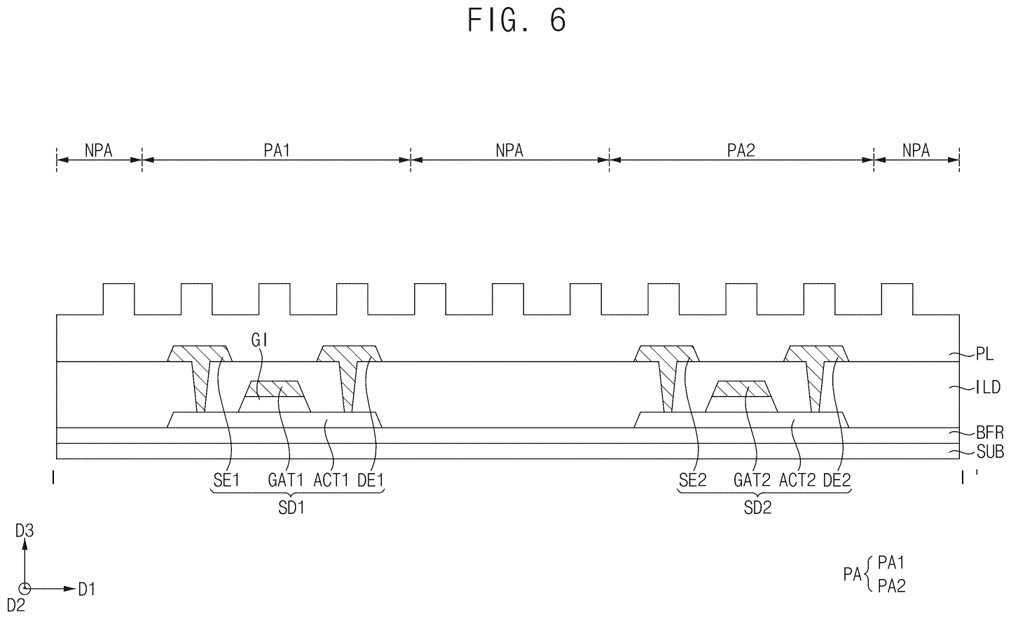

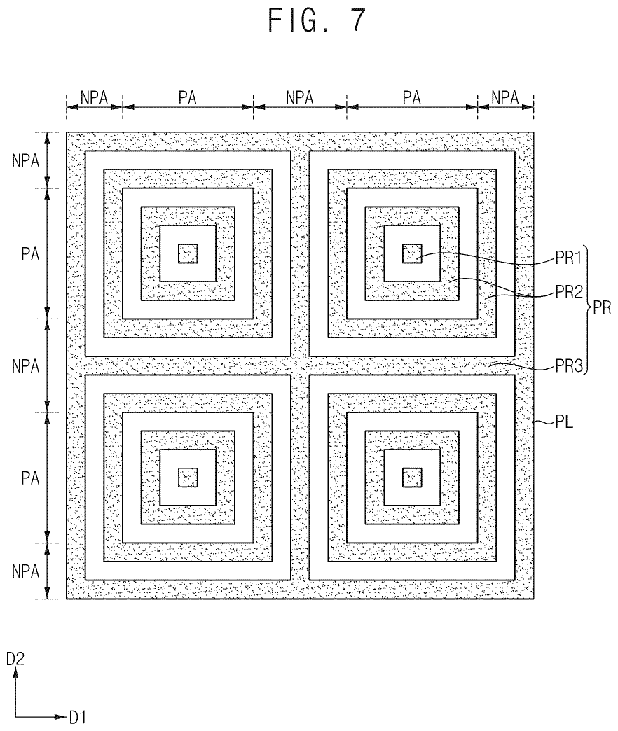

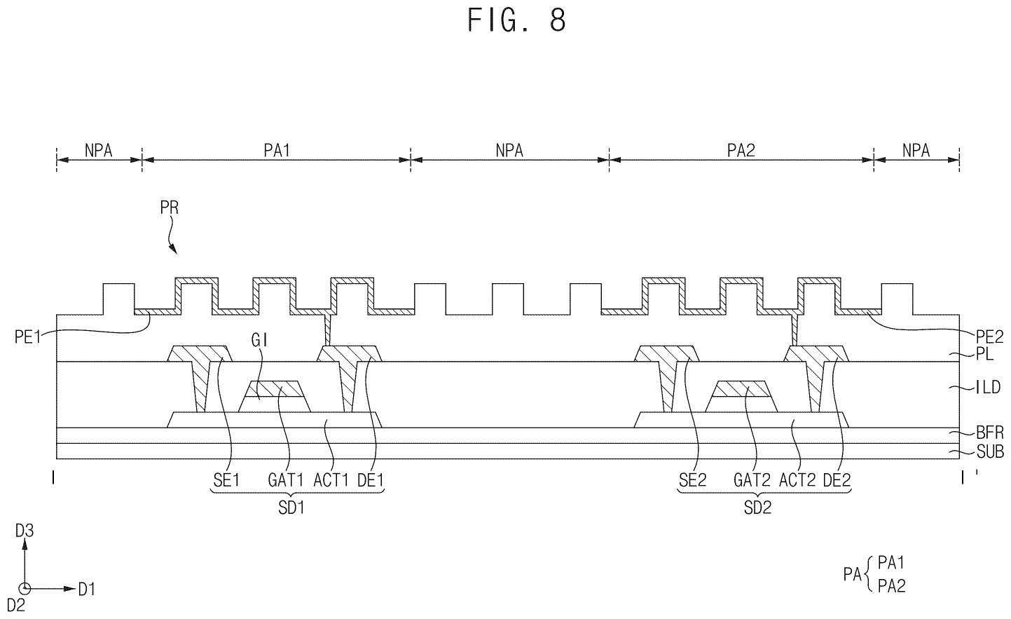

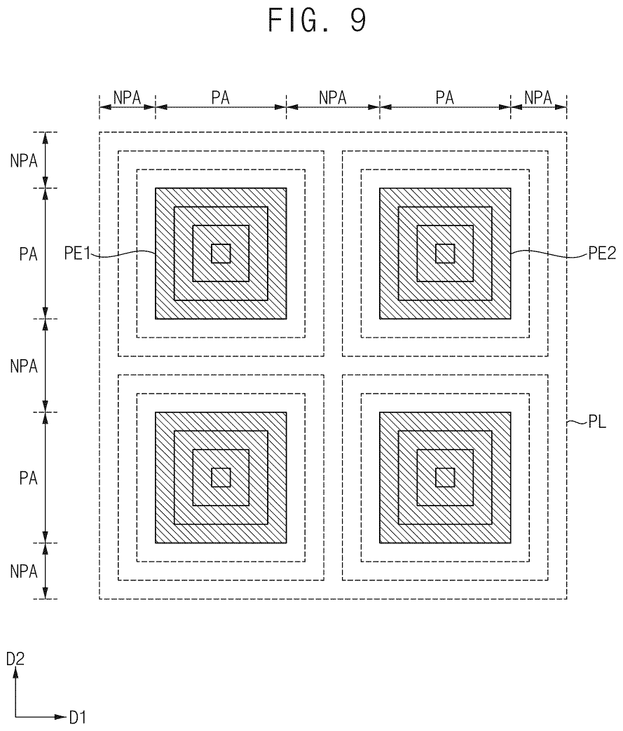

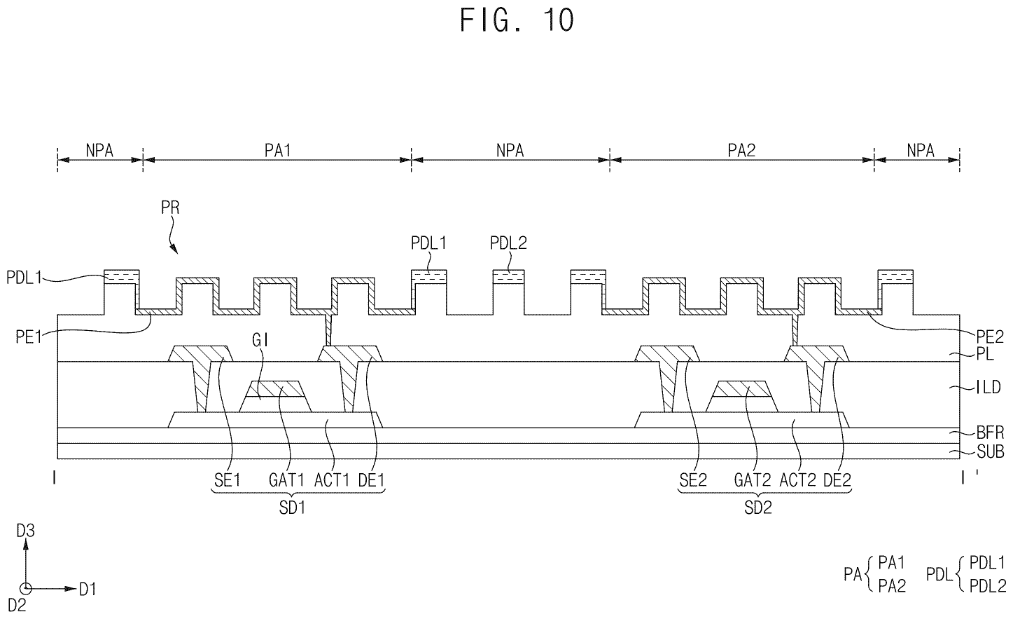

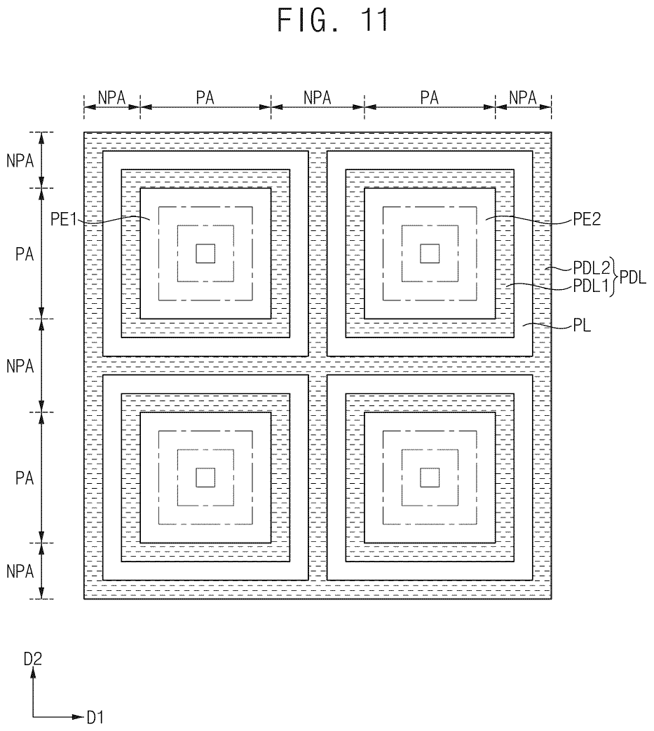

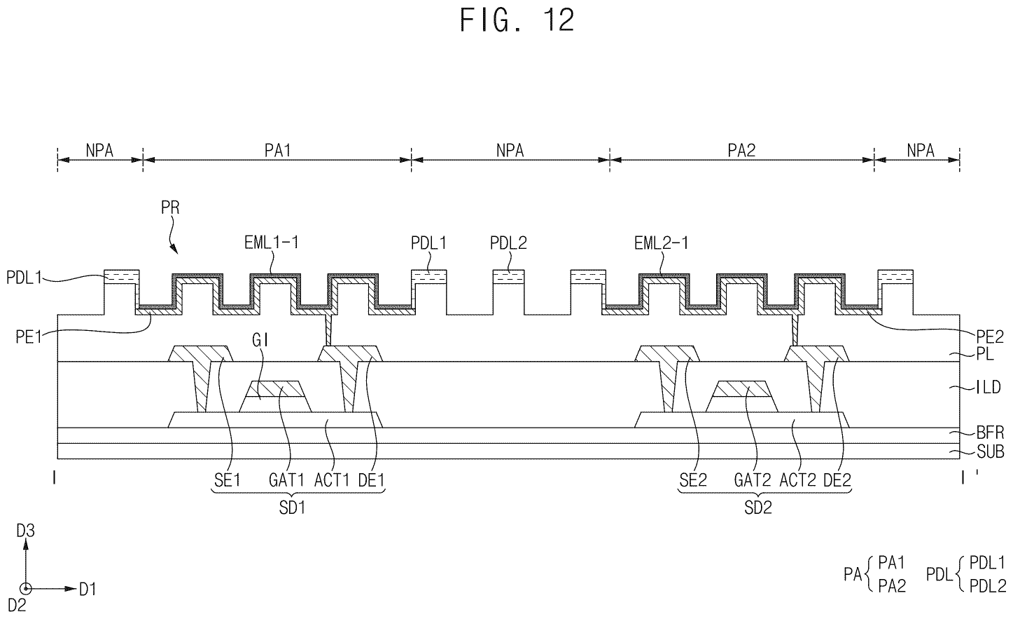

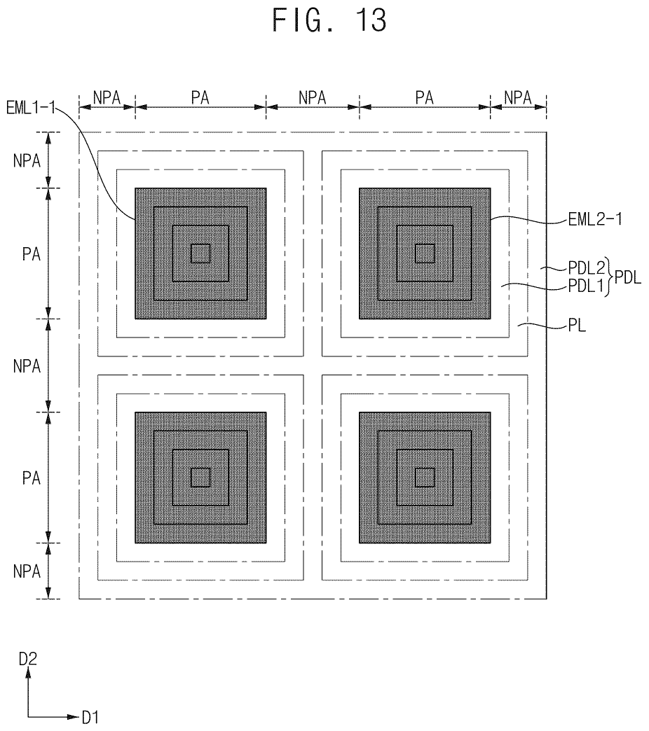

FIGS. 6 to 16 are views for illustrating an embodiment of a method of manufacturing the display device of FIG. 3. Particularly, FIG. 7 may be a plan view for illustrating the planarization layer PL of FIG. 6, FIG. 9 may be a plan view for illustrating the first and second pixel electrodes PE1 and PE2 of FIG. 8, FIG. 11 may be a plan view illustrating the pixel defining layer PDL of FIG. 10, and FIG. 13 may be a plan view illustrating the first and second lower light emitting layers EML1-1 and EML2-1 of FIG. 12.

Referring to FIGS. 6 and 7, the buffer layer BFR, the first and second active patterns ACT1 and ACT2, the gate insulating layer GI, the first and second gate electrodes GAT1 and GAT2, the interlayer insulating layer ILD, the first and second source electrodes SE1 and SE2, the first and second drain electrodes DE1 and DE2, and the planarization layer PL may be sequentially formed (or provided) on the substrate SUB.

The planarization layer PL may overlap the pixel area PA and the non-pixel area NPA, and may include the plurality of protrusions PR protruding in the third direction D3.

Each of the protrusions PR may have a planar shape surrounding a center of the pixel area PA. The center of the pixel area PA may be repeatedly arranged along the first direction D1 and the second direction D2. In an embodiment, the protrusions PR may include a first protrusion PR1 overlapping the center of the pixel area PA, at least one second protrusion PR2 surrounding the first protrusion PR1, and a third protrusion PR3 surrounding the second protrusion PR2. In an embodiment, for example, the first protrusion PR1 may have a rectangular planar shape, and each of the second protrusions PR2 may have a hollow quadrangular planar shape.

The first protrusion PR1, the second protrusion PR2 and the third protrusion PR3 may be spaced apart from each other. In an embodiment, for example, the third protrusion PR3 may be formed to overlap the non-pixel area NPA and surround each of the centers of the pixel area PA. That is, the third protrusion PR3 may have a lattice shape on a plane.

Although an embodiment where two second protrusions PR2 are provided is shown in FIG. 7, the disclosure is not limited thereto. In an embodiment, for example, the number of the second protrusion PR2 in each pixel area may be one or three or more.

Referring to FIGS. 8 and 9, the first and second pixel electrodes PE1 and PE2 may be formed (or provided) on the planarization layer PL. Each of the first and second pixel electrodes PE1 and PE2 may be formed along the profile of the planarization layer PL in the pixel area PA. In an embodiment, each of the first and second pixel electrodes PE1 and PE2 may be formed along the profile of the protrusions PR of the planarization layer PL in the pixel area PA.

In an embodiment, each of the first and second pixel electrodes PE1 and PE2 may be formed to overlap the pixel area PA. In an embodiment, the first pixel electrode PE1 may overlap the first pixel area PA1, and the second pixel electrode PE2 may overlap the second pixel area PA2.

Referring to FIGS. 10 and 11, a preliminary pixel defining layer may be formed on the planarization layer PL, the first pixel electrode PE1 and the second pixel electrode PE2. The pixel defining layer PDL may be formed by patterning the preliminary pixel defining layer. The pixel defining layer PDL may include the first pixel defining layer PDL1 and the second pixel defining layer PDL2 spaced apart from the first pixel defining layer PDL1.

The first pixel defining layer PDL1 may be formed to surround the first and second pixel electrodes PE1 and PE2 on a plane. In addition, the first pixel defining layer PDL1 may be formed to contact a portion of each of the first and second pixel electrodes PE1 and PE2 and one side surface of a protrusion (e.g., a protrusion at a boundary between the non-pixel area NPA and the pixel area PA) among the protrusions PR. In an embodiment, for example, the protrusion may be the second protrusion PR2. That is, the first pixel defining layer PDL1 may be formed to overlap the second protrusion PR2.

The second pixel defining layer PDL2 may be formed to surround the first pixel defining layer PDL1 on a plane and to overlap another protrusion (e.g., a protrusion in the non-pixel area NPA) among the protrusions PR. In an embodiment, for example, the another protrusion may be the third protrusion PR3. That is, the second pixel defining layer PDL2 may be formed to overlap the third protrusion PR3. In other words, the second pixel defining layer PDL2 may be formed to overlap the non-pixel area NPA and to surround each of the centers of the pixel area PA. That is, the second pixel defining layer PDL2 may have a lattice shape on a plane.

Referring to FIGS. 12 and 13, the first lower light emitting layer EML1-1 may be formed on the first pixel electrode PE1, and the second lower light emitting layer EML2-1 may be formed on the second pixel electrode PE2. Each of the first and second lower light emitting layers EML1-1 and EML2-1 may be formed along the respective profiles of the first and second pixel electrodes PE1 and PE2.

In an embodiment, each of the first and second lower light emitting layers EML1-1 and EML2-1 may be formed to overlap the pixel area PA. In such an embodiment, the first lower light emitting layer EML1-1 may overlap the first pixel area PA1, and the second lower light emitting layer EML2-1 may overlap the second pixel area PA2.

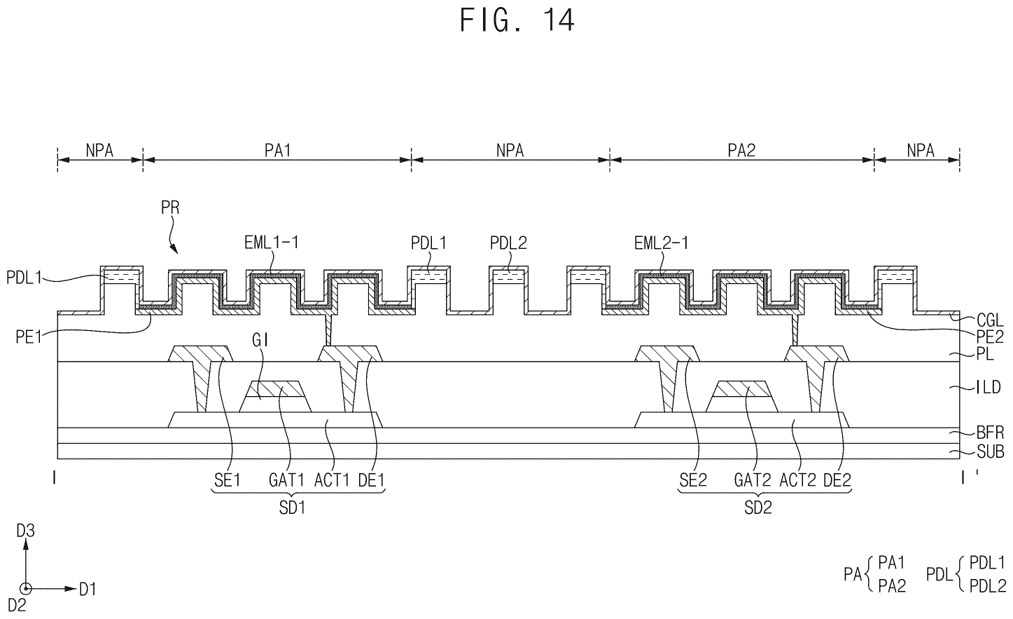

Referring to FIG. 14, the charge generation layer CGL may be formed on the first and second lower light emitting layers EML1-1 and EML2-1. The charge generation layer CGL may continuously extend from the pixel area PA to the non-pixel area NPA. That is, the charge generation layer CGL may be entirely formed in the display area DA. The charge generation layer CGL may be formed along the profile of the first and second lower light emitting layers EML1-1 and EML2-1, the pixel defining layer PDL and the planarization layer PL.

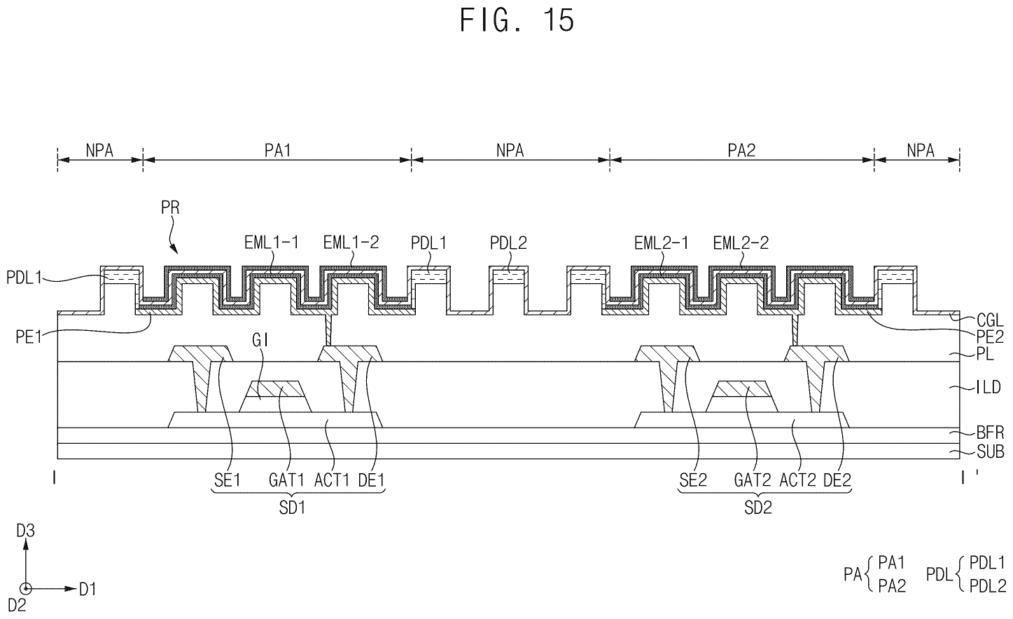

Referring to FIG. 15, the first and second upper light emitting layers EML1-2 and EML2-2 may be formed on the charge generation layer CGL. Each of the first and second upper light emitting layers EML1-2 and EML2-2 may be formed along the profile of the charge generation layer CGL.

In an embodiment, each of the first and second upper light emitting layers EML1-2 and EML2-2 may be formed to overlap the pixel area PA. In such an embodiment, the first upper light emitting layer EML1-2 may overlap the first pixel area PA1 and the first lower light emitting layer EML1-1, and the second upper light emitting layer EML2-2 may overlap the second pixel area PA2 and the second lower light emitting layer EML2-1.

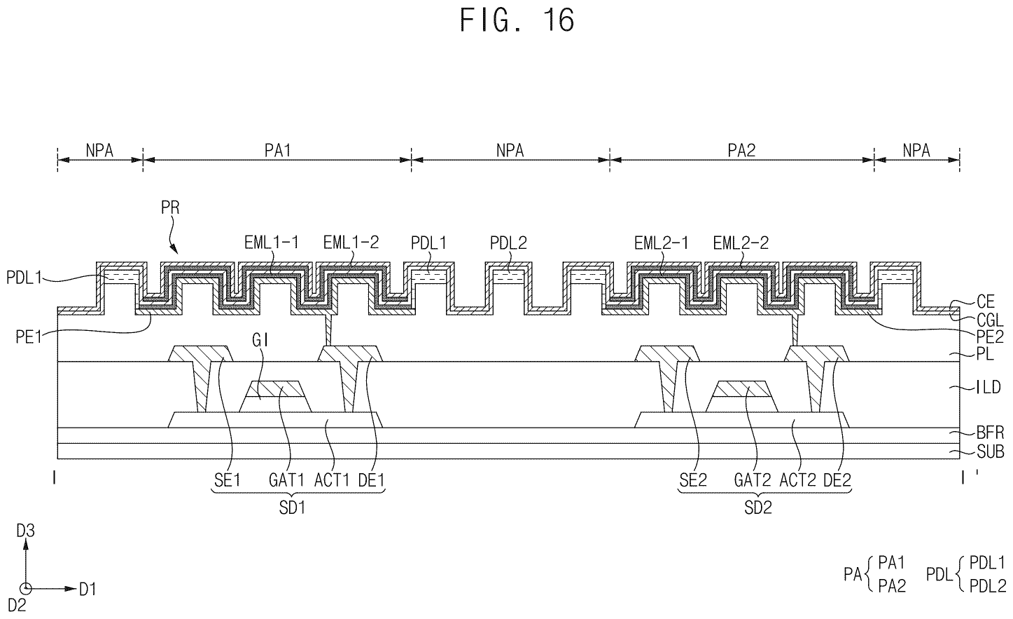

Referring to FIG. 16, a common electrode CE may be formed on the first and second upper light emitting layers EML1-2 and EML2-2. In an embodiment, common electrode CE may be entirely formed in the pixel area PA and the non-pixel area NPA. The common electrode CE may be formed along the profile of the first and second upper light emitting layers EML1-2 and EML2-2 and the charge generation layer CGL.

Referring back to FIG. 3, the encapsulation layer TFE may be formed on the common electrode CE. The encapsulation layer TFE may be formed to sufficiently cover the common electrode CE. Accordingly, the display device 10 shown in FIG. 3 may be manufactured.

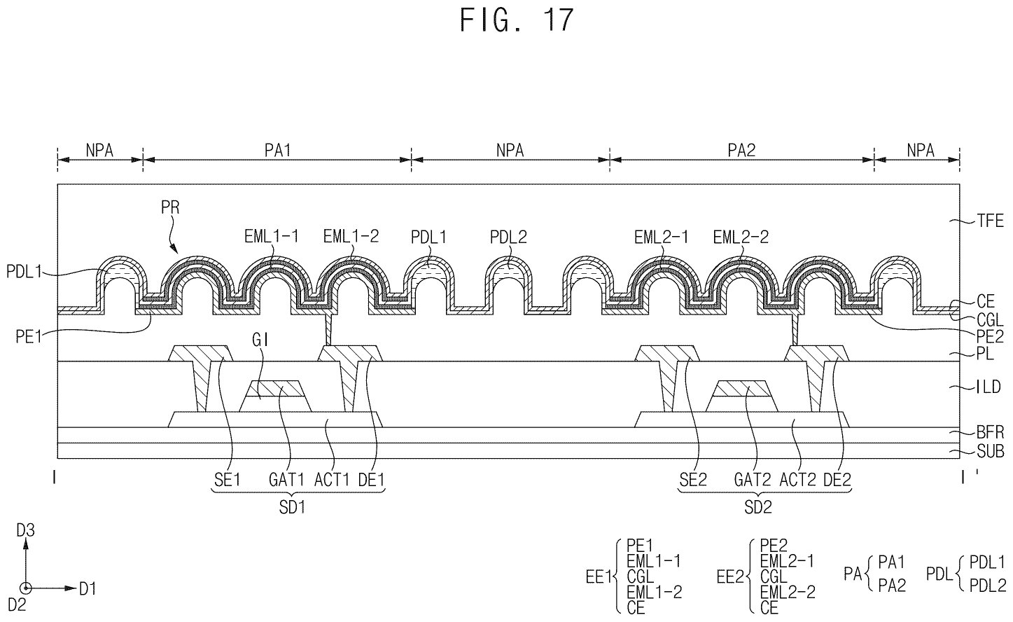

FIG. 17 is a cross-sectional view corresponding to FIG. 3, illustrating an alternative embodiment.

Referring to FIG. 17, an embodiment of the display device 10 may include the substrate SUB, the buffer layer BFR, the first semiconductor element SD1, the second semiconductor element SD2, the gate insulating layer GI, the interlayer insulating layer ILD, the planarization layer PL, the first and second pixel electrodes PE1 and PE2, the pixel defining layer PDL, the first and second lower light emitting layers EML1-1 and EML2-1, the charge generation layer CGL, the first and second upper light emitting layers EML1-2 and EML2-2, the common electrode CE, and the encapsulation layer TFE.

Hereinafter, any repetitive detailed descriptions of the same or like elements as those of the display device 10 described above with reference to FIG. 3 will be omitted or simplified.

In an embodiment, the planarization layer PL may include the plurality of protrusions PR. In such an embodiment, the planarization layer PL may overlap the pixel area PA and the non-pixel area NPA, and may include the plurality of protrusions PR protruding in the third direction D3 from the upper surface of the planarization layer PL.

In an embodiment, for example, each of the protrusions PR may have a semicircular or semielliptical cross-sectional shape. However, the cross-sectional shape of each of the protrusions PR is not limited thereto, and each of the protrusions PR may have various cross-sectional shapes.

Embodiments of the disclosure can be applied to various display devices. In an embodiment, for example, the disclosure is applicable to various display devices such as display devices for vehicles, ships and aircraft, portable communication devices, display devices for exhibition or information transmission, medical display devices, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a pixel area and a non-pixel area adjacent to the pixel area;
a planarization layer disposed on the substrate and including a plurality of protrusions each having a planar shape surrounding a center of the pixel area;
a pixel electrode disposed on the planarization layer and overlapping the pixel area;
a pixel defining layer disposed on the planarization layer, overlapping the non-pixel area, and exposing a portion of the pixel electrode;
a lower light emitting layer disposed on the pixel electrode;
a charge generation layer disposed on the lower light emitting layer; and
an upper light emitting layer disposed on the charge generation layer.

2. The display device of claim 1, wherein the charge generation layer is continuously disposed over the pixel area and the non-pixel area.

3. The display device of claim 1, wherein the pixel electrode is disposed along a profile of the planarization layer.

4. The display device of claim 1, wherein
the pixel defining layer includes a first pixel defining layer contacting a portion of the pixel electrode and a second pixel defining layer surrounding the first pixel defining layer on a plane, and
the first pixel defining layer and the second pixel defining layer are spaced apart from each other.

5. The display device of claim 4, wherein the first pixel defining layer contacts one side surface of a protrusion among the protrusions, and the second pixel defining layer overlaps another protrusion among the protrusions.

6. The display device of claim 1, wherein the lower light emitting layer and the upper light emitting layer overlap the pixel area.

7. The display device of claim 6, wherein the lower light emitting layer is disposed along a profile of the pixel electrode.

8. The display device of claim 6, wherein the upper light emitting layer is disposed along a profile of the charge generation layer.

9. The display device of claim 1, further comprising:
a common electrode disposed on the upper light emitting layer.

10. The display device of claim 9, wherein the common electrode is continuously disposed over the pixel area and the non-pixel area.

11. The display device of claim 1, wherein the protrusions include:
a first protrusion overlapping a center of the pixel area;
at least one second protrusion surrounding the first protrusion; and
a third protrusion surrounding the second protrusion.

12. The display device of claim 11, wherein each of the protrusions has a polygonal cross-sectional shape.

13. The display device of claim 11, wherein each of the protrusions has a semicircular or semielliptical cross-sectional shape.

14. The display device of claim 1, wherein the charge generation layer includes a first charge generation layer disposed on the lower light emitting layer and a second charge generation layer disposed on the first charge generation layer.

15. The display device of claim 1, further comprising:
an electron transport layer respectively disposed on the lower light emitting layer and on the upper light emitting layer.

16. The display device of claim 1, further comprising:
a hole transport layer respectively disposed under the lower light emitting layer and under the upper light emitting layer.

17. A display device comprising:
a substrate including a first pixel area which emits a first light, a second pixel area which emits a second light different from the first light, and a non-pixel area adjacent to the first pixel area and the second pixel area;
a planarization layer disposed on the substrate and including a plurality of protrusions each having a planar shape surrounding a center of the first pixel area and a center of the second pixel area;
a first pixel electrode disposed on the planarization layer and overlapping the first pixel area;
a second pixel electrode disposed on the planarization layer and overlapping the second pixel area;
a pixel defining layer disposed on the planarization layer, overlapping the non-pixel area, and exposing a portion of each of the first pixel electrode and the second pixel electrode;
a first lower light emitting layer disposed on the first pixel electrode;
a second lower light emitting layer disposed on the second pixel electrode;
a charge generation layer disposed on the first lower light emitting layer and the second lower light emitting layer;
a first upper light emitting layer disposed on the charge generation layer and overlapping the first lower light emitting layer; and
a second upper light emitting layer disposed on the charge generation layer and overlapping the second lower light emitting layer.

18. The display device of claim 17, wherein the charge generation layer is continuously disposed over the first and second pixel areas and the non-pixel area.

19. The display device of claim 17, wherein the first and second pixel electrodes are disposed along a profile of the planarization layer.

20. The display device of claim 17, wherein the pixel defining layer includes a first pixel defining layer contacting portions of the first and second pixel electrodes and a second pixel defining layer surrounding the first pixel defining layer on a plane, and
the first pixel defining layer and the second pixel defining layer are spaced apart from each other.
